(19) United States
(12) Patent Application Publication
(10) Pub. No.: US 2010/0159655 A1
(43) Pub. Date: Jun. 24, 2010

(54) SEMICONDUCTOR MEMORY DEVICE AND METHOD OF MANUFACTURING SEMICONDUCTOR MEMORY DEVICES

(75) Inventor: Masato ENDO, Ashigarakami-gun (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/714,843

(22) Filed: Mar. 1, 2010

Related U.S. Application Data
(62) Division of application No. 11/761,793, filed on Jun. 12, 2007.

(30) Foreign Application Priority Data
Jun. 16, 2006 (JP) 2006-167741

(51) Int. Cl. H01L 21/336

(52) U.S. Cl. 438/266; 257/E21.422

(57) ABSTRACT

A semiconductor memory device has a floating gate formed on a semiconductor substrate at certain intervals along a plane with a first insulator interposed therebetween, and a control gate formed on the layer of floating gates with a second insulator interposed therebetween. The device includes a semiconductor layer formed by selectively epitaxially growing the semiconductor substrate between the floating gates on the semiconductor substrate with a third insulator interposed therebetween.

### CROSS-REFERENCE TO RELATED APPLICATION

This application is a divisional application based on application Ser. No. 11/761,793, filed Jun. 12, 2007 and claims the benefit of priority from the prior Japanese Patent Application No. 2006-167741, filed on Jun. 16, 2006, the entire contents of which are incorporated herein by reference.

### BACKGROUND OF THE INVENTION

1. Field of the Invention

The present invention relates to an electrically erasable and programmable semiconductor memory device having a control gate and a floating gate, and a method of manufacturing such semiconductor memory devices.

2. Description of the Related Art

Conventionally known semiconductor memory devices include electrically erasable and programmable, non-volatile semiconductor memory devices (EEPROM). Among those, attention has been focused on a NAND-type EEPROM as a high integration technology, which includes NAND cells each consisting of a plurality of serially connected memory cells each serving as a unit for storing one bit data. The NAND-type EEPROM may be used in memory cards for storing image data from digital still cameras.

The memory cell in the NAND-type EEPROM has an FET-MOS structure in which a floating gate (charge accumulation layer) and a control gate (CG) are stacked on a semiconductor substrate serving as a channel region with an insulator interposed therebetween. The control gate is connected to a word line (WL). The NAND cell consists of the plurality of memory cells serially connected, with adjacent ones sharing a source/drain. The source/drain means an impurity region that has a function of serving as at least one of a source and a drain.

In the semiconductor memory device, however, recent fine pattering of the NAND cell shortens the interval between adjacent cells, increases the capacity between floating gates in adjacent cells, and increases the interference between cells as a problem.

JP-A 2005-217391 describes a high-performance field effect device. This device comprises a crystalline Si body; an SiGe layer serving as a buried channel for holes and epitaxially grown on the Si body; an Si layer serving as a surface channel for electrons and epitaxially grown on the SiGe layer; and a source/drain containing a distorted SiGe layer epitaxially grown of the conduction type different from the Si body.

Also in the device disclosed in JP-A 2005-217391, however, a shortened interval between adjacent cells encompasses the above-described problem.

### SUMMARY OF THE INVENTION

In an aspect the present invention provides a semiconductor memory device having a floating gate formed on a semiconductor substrate at certain intervals along a plane with a first insulator interposed therebetween, and a control gate formed on the layer of floating gates with a second insulator interposed therebetween. The device comprises a semiconductor layer formed by selectively epitaxially growing the semiconductor substrate between the floating gates on the semiconductor substrate with a third insulator interposed therebetween.

In another aspect the present invention provides a method of manufacturing semiconductor memory devices having a floating gate formed on a first insulator provided on a semiconductor substrate and arranged at certain intervals along a plane, and a control gate formed on a second insulator provided on the layer of floating gates. The method comprises forming a third insulator on sides in the layer of floating gates; and forming a semiconductor layer between adjacent portions of the third insulator by selectively epitaxially growing the semiconductor substrate.

In yet another aspect the present invention provides a method of manufacturing semiconductor memory devices having a floating gate formed on a first insulator provided on a semiconductor substrate and arranged at certain intervals along a plane, and a control gate formed on a second insulator provided on the layer of floating gates. The method comprises forming a third insulator on sides in the layer of floating gates; and forming a semiconductor layer between adjacent portions of the third insulator by selectively epitaxially growing the semiconductor substrate, the semiconductor layer having an upper surface located lower than the upper surface of the layer of floating gates.

### BRIEF DESCRIPTION OF THE DRAWINGS

FIG. 1 is a plan view of a NAND-type flash EEPROM (non-volatile semiconductor memory device) according to an embodiment of the present invention.

FIG. 2A is a cross-sectional view showing the NAND-type flash EEPROM in process step order.

FIG. 2B is a cross-sectional view showing the NAND-type flash EEPROM in process step order.

FIG. 3A is a cross-sectional view showing the NAND-type flash EEPROM in process step order.

FIG. 3B is a cross-sectional view showing the NAND-type flash EEPROM in process step order.

FIG. 4A is a cross-sectional view showing the NAND-type flash EEPROM in process step order.

FIG. 4B is a cross-sectional view showing the NAND-type flash EEPROM in process step order.

FIG. 5A is a cross-sectional view showing the NAND-type flash EEPROM in process step order.

FIG. 5B is a cross-sectional view showing the NAND-type flash EEPROM in process step order.

FIG. 6A is a cross-sectional view showing the NAND-type flash EEPROM in process step order.

FIG. 6B is a cross-sectional view showing the NAND-type flash EEPROM in process step order.

FIG. 7A is a cross-sectional view showing the NAND-type flash EEPROM in process step order.

FIG. 7B is a cross-sectional view showing the NAND-type flash EEPROM in process step order.

FIG. 8A is a cross-sectional view showing the NAND-type flash EEPROM in process step order.

FIG. 8B is a cross-sectional view showing the NAND-type flash EEPROM in process step order.

FIG. 9A is a cross-sectional view showing the NAND-type flash EEPROM in process step order.

FIG. 9B is a cross-sectional view showing the NAND-type flash EEPROM in process step order.

FIG. 10A is a cross-sectional view showing the NAND-type flash EEPROM in process step order.

FIG. 10B is a cross-sectional view showing the NAND-type flash EEPROM in process step order.

FIG. 11A is a cross-sectional view showing the NAND-type flash EEPROM in process step order.

FIG. 11B is a cross-sectional view showing the NAND-type flash EEPROM in process step order.

FIG. 12A is a cross-sectional view showing the NAND-type flash EEPROM in process step order.

FIG. 12B is a cross-sectional view showing the NAND-type flash EEPROM in process step order.

### DETAILED DESCRIPTION OF THE EMBODIMENTS

The embodiment of the present invention will now be described below with reference to the drawings.

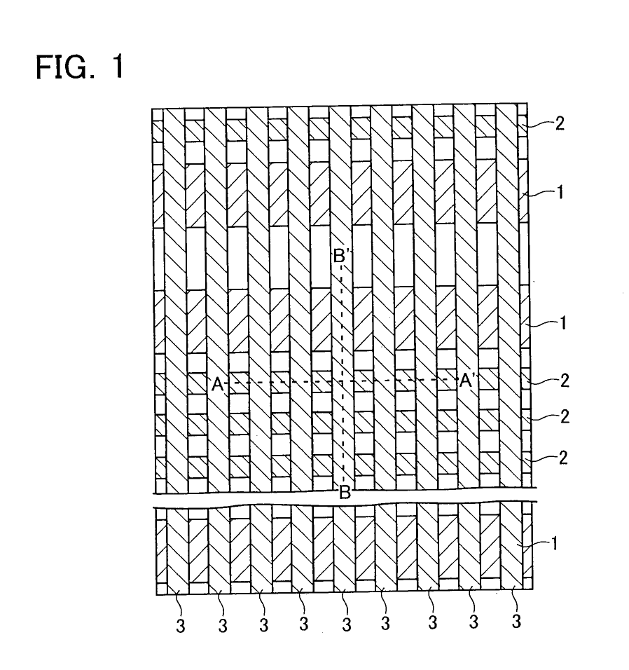

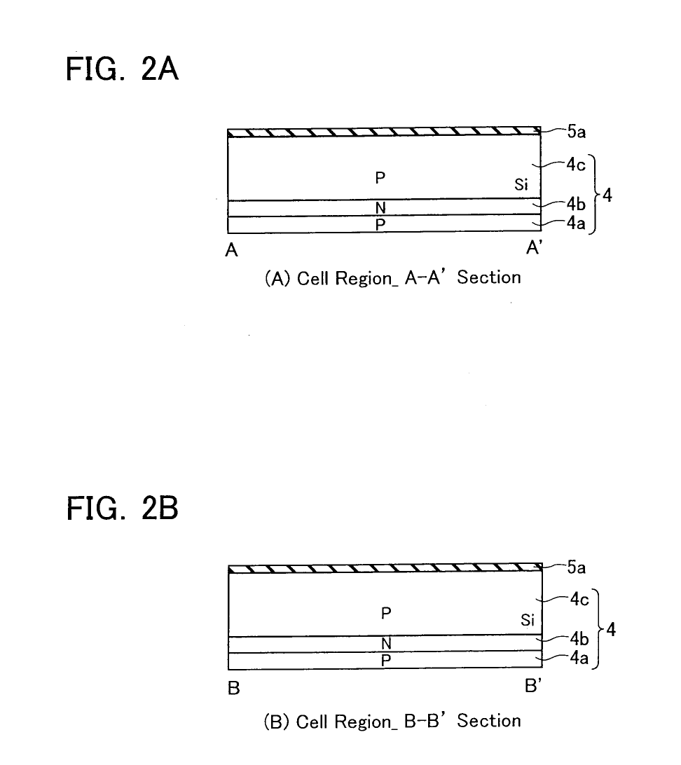

FIG. 1 is a plan view of a cell region in a NAND-type flash EEPROM (non-volatile semiconductor memory device) according to an embodiment of the present invention, and FIGS. 2A-12A (2B-12B) are cross-sectional views in process step order. FIGS. 2A-12A are cross-sectional views taken along A-A′ in FIG. 1, and FIGS. 2B-12B are cross-sectional views taken along B-B′ in FIG. 1.

In FIG. 1, within a memory cell array formation region, there are formed selection gates 1 laterally extending in the figure, and a plurality of word lines 2 sandwiched between a pair of the selection gates 1 and extending in parallel with the selection gate 1. On these selection gates 1 and word lines 2, there are formed a plurality of bit lines 3 extending in a direction orthogonal to them. Cell transistors are formed at intersections of the word lines 2 and the bit lines 3.

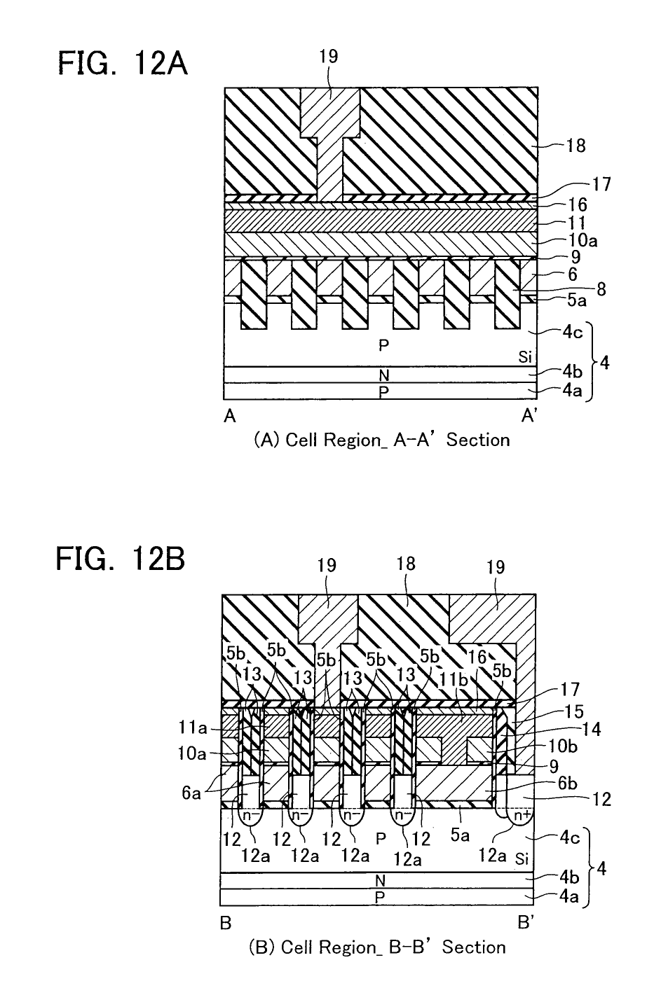

In FIGS. 2A-12A (2B-12B), a semiconductor substrate or silicon substrate 4 has a well structure in which an n-type well 4b is formed in a p-type silicon substrate 4a, and a p-type well 4c is formed in a region of the n-type well 4b corresponding to the memory cell array. The silicon substrate 4 is sectioned by device isolations 8 as shown in FIGS. 12A, 12B to form device formation regions in the form of stripes isolated from each other. The device formation region narrower in the B-B′ direction functions as a memory cell transistor while the device formation region wider in the B-B′ direction functions as a selection gate transistor. In each device formation region functioning as the memory cell transistor, a floating gate 6a is formed on the silicon substrate 4 with a first insulator 5a interposed therebetween. Further, double-layered control gates 10a, 11a are formed on the floating gate 6a with a tunnel oxide or second insulator 9 interposed therebetween. In each device formation region for the selection gate transistor, double-layered control gates 10b, 11b are formed on a floating gate 6b with a tunnel oxide or second insulator 9 interposed therebetween. A silicide film 16 is formed over the upper surfaces of the control gates 11a, 11b. Thus, the EEPROM of the present embodiment is configured to inject charge not from the silicon substrate 4 but from the control gates 10a, 11b, 11a, 11b through the tunnel oxide or second insulator 9 into the floating gates 6a, 6b.

The floating gates 6a, 6b are separated on a memory cell basis while the control gates 10a, 11a, 10b, 11b and the silicide film 16 form the word lines 2 that are common to a plurality of memory cells and continue in one direction. The floating gates 6a, 6b may use a film of polysilicon or a charge accumulation layer of insulator. On sides exposed in B-B′ section of the floating gates 6a, 6b, the second insulator 9 and the control gates 10a, 11a, 10b, 11b, there is formed a third insulator 5b equal to the first insulator 5a. Between the floating gates 6a, 6b that adjoin in the direction of the bit line 3, there is formed an epitaxial layer 12 epitaxially grown from the silicon substrate 4 with the third insulator 5b interposed therebetween. The epitaxial layer 12 contains a diffusion region 12a there beneath that is formed on epitaxial growth to serve as a source/drain region. A forth insulator 13 is formed over the epitaxial layer 12.

The memory cell array thus configured is covered with interlayer insulators 17, 18 on which the bit lines 3 are formed. Through the interlayer insulator 17, there are formed contact plugs 19 composed of metal, which contact the source region of the selection gate transistor and the silicide film 16 on the control gates 10a, 11a of the memory cell transistor, respectively.

The following description is given to the process steps of manufacturing the NAND-type flash EEPROM according to the embodiment.

First, as shown in FIGS. 2A, 2B, the n-type well 4b is formed in the p-type silicon substrate 4a, and the p-type well 4c is formed in the region of the n-type well 4b corresponding to the memory cell array. Over such the silicon substrate 4, which is composed of, for example, Si or SiGe, the first insulator 5a is formed.

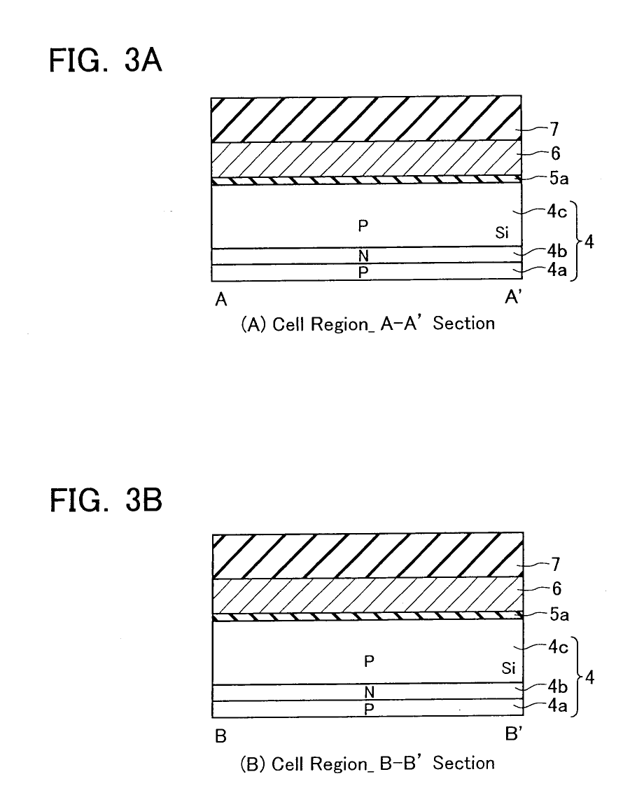

Subsequently, as shown in FIGS. 3A, 3B, a first electrode film 6 is deposited, which is to be turned into the floating gates 6a and 6b of the memory cell transistor and the selection gate transistor. Then, a mask material 7 is deposited over the first electrode film 6.

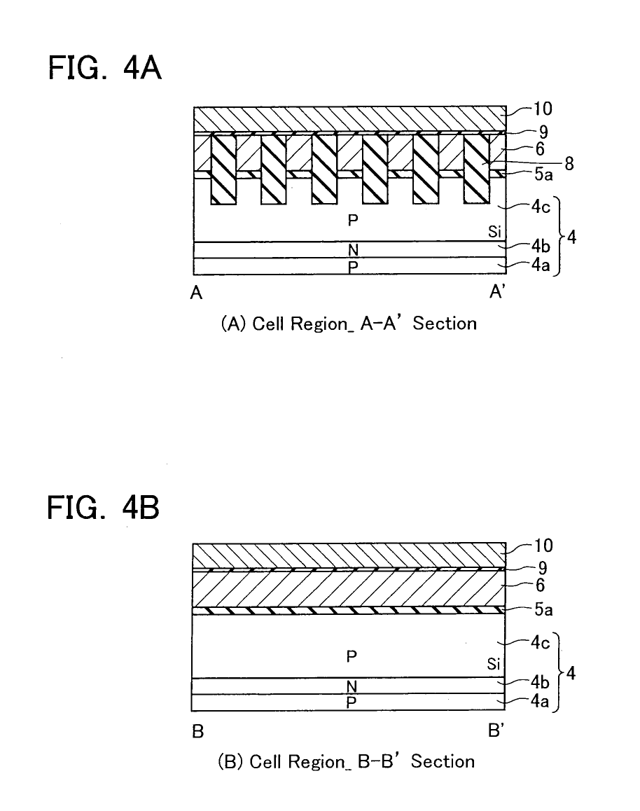

Next, as shown in FIGS. 4A, 4B, lithography and etching technologies are used to form device isolation regions composed of the device isolation film 8, followed by peeling off the mask material 7. Then, over the entire surface, the second insulator 9 is deposited, which is to be turned into the tunnel insulator between gates of the cell transistor. Further, a second electrode film 10 is deposited, which is used to form the control gate 10a of the cell transistor.

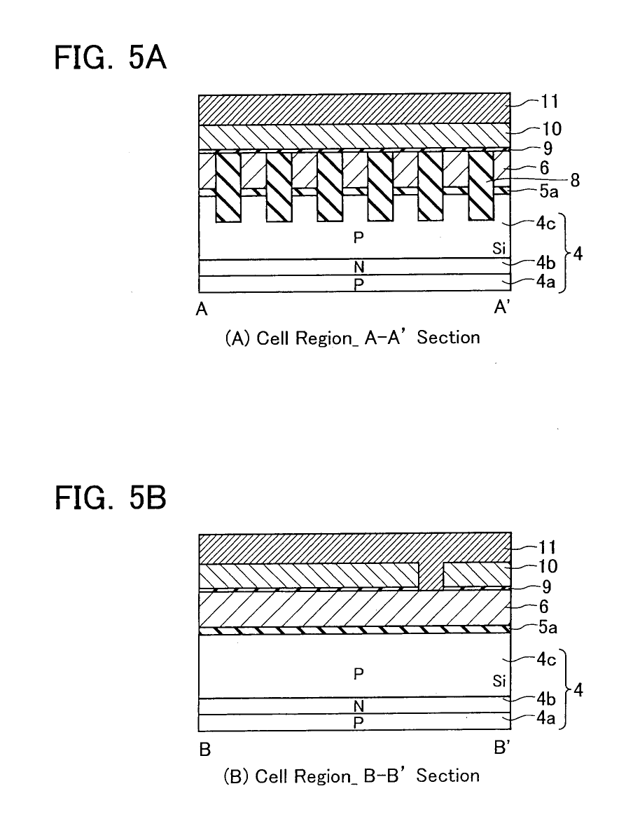

Next, as shown in FIGS. 5A, 5B, on the second electrode film 10, a third electrode film 11 is formed, which is used to form the control gate 11a. In order to electrically connect the third electrode film 11 with the first electrode film 6, the second electrode film 10 and the second insulator 9 are peeled off partly or entirely from the gate region of the selection gate 1 of the cell transistor, followed by depositing the third electrode film 11, which is to be turned into the gate electrode of the selection gate 1 of the cell transistor.

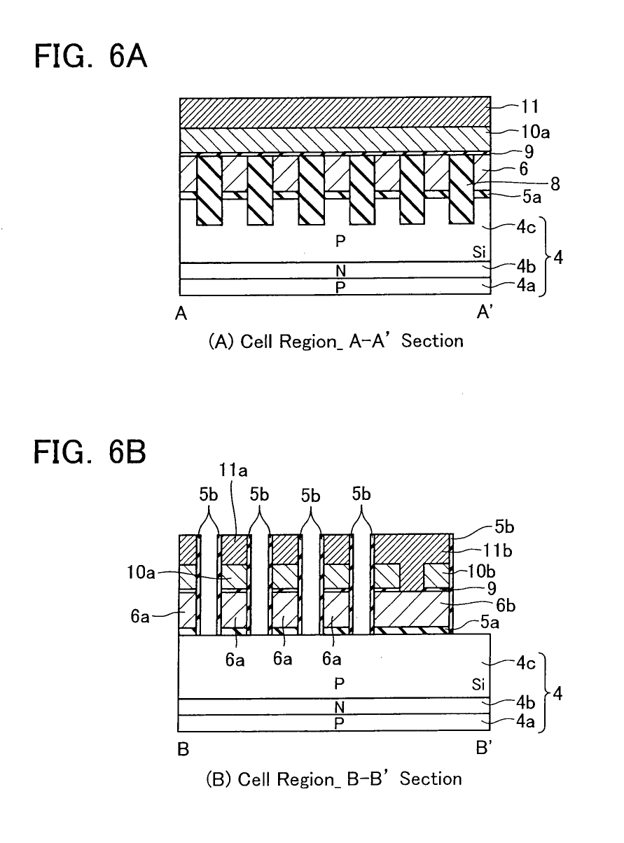

Next, as shown in FIGS. 6A, 6B, lithography and etching technologies are used to form trenches at certain intervals. The trench has a width in the B-B′ direction and a depth extending to the upper surface of the silicon substrate 4. Subsequently, on the sides of the trenches formed through film formation and etching technologies, the third insulator 5b is formed. In the vicinity of the region from which the second electrode film 10 and the second insulator 9 are peeled off, a trench is formed wider in the B-B′ direction. The first insulator 5a is formed beneath the first electrode film 6 while the third insulator 5b is formed on the sides of the first electrode film 6. The first insulator 5a and the third insulator 5b may be composed of either the same material or different types of material.

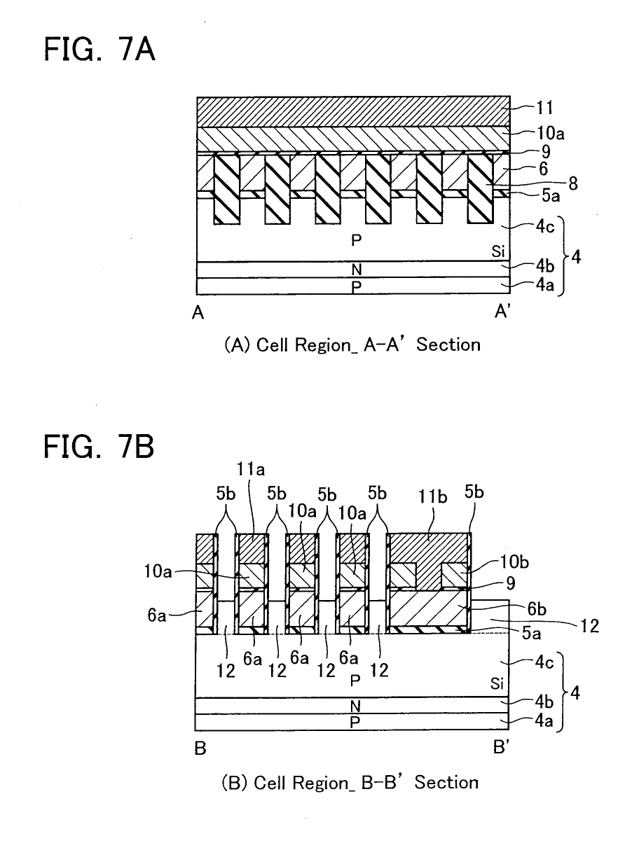

Next, as shown in FIGS. 7A, 7B, a selective epitaxial layer 12 is formed by selectively epitaxially growing the silicon substrate 4 of which upper surface is exposed through the trenches formed in FIGS. 6A, 6B. Therefore, if the silicon substrate 4 is composed of Si or SiGe, for example, the selective epitaxial layer 12 is also composed of Si or SiGe. Another step may be used to deposit a semiconductor layer other than the selective epitaxial layer 12.

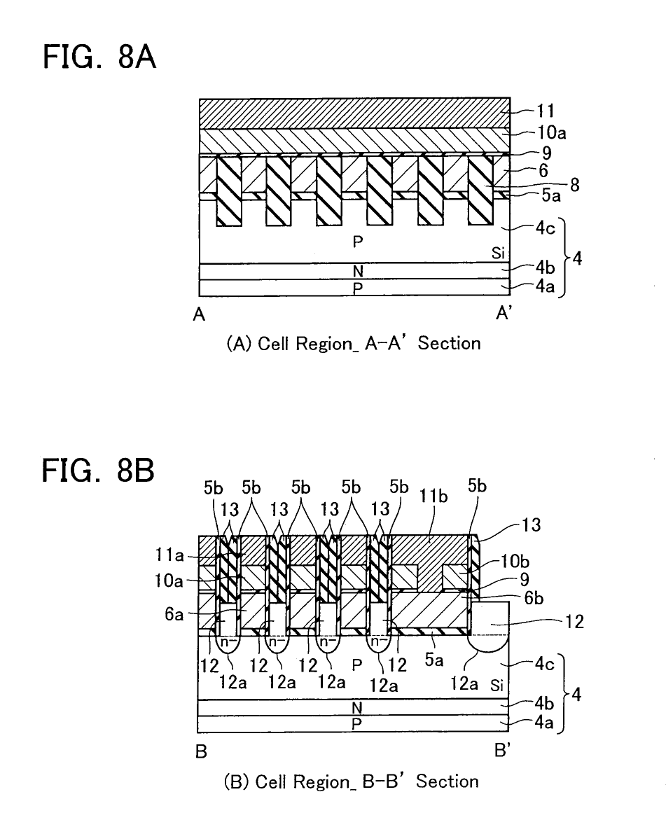

Subsequently, as shown in FIGS. 8A, 8B, after formation of the gate electrode, ions of an n-type impurity such as phosphorous (P) are implanted into the selective epitaxial layer 12 to form an n-type impurity layer 12a in a region extending from the selective epitaxial layer 12 into the silicon substrate 4. The impurity layer 12a forms a source/drain region of a memory cell. On the selective epitaxial layer 12, a fourth insulator 13 is deposited up to the top of the trench. In the trench made wider in the B-B′ direction and located in the vicinity of the region from which the second electrode film 10 and the second insulator 9 are peeled off, the fourth insulator 13 is deposited only on a side. Desirably, the upper surface of the selective epitaxial layer 12 formed through the above steps locates lower than the upper surface of the second electrode film 6. More preferably, the upper surface of the selective epitaxial layer 12 locates at ⅓ to ¾ of the height from the lower surface of the second electrode film 6.

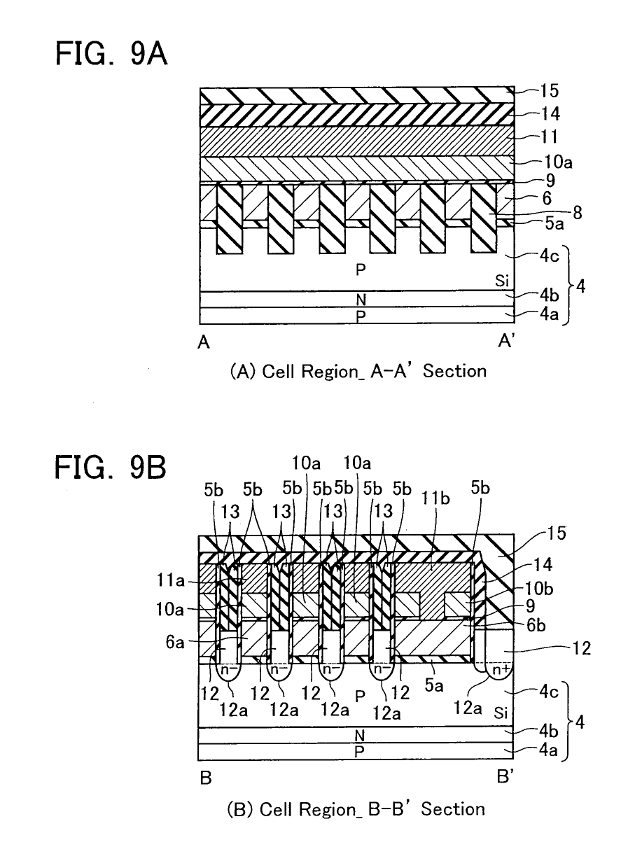

Next, as shown in FIGS. 9A, 9B, after peeling off the fourth insulator 13 formed only on the gate side of the selection gate 1 of the cell transistor through the lithography and etching technologies, a fifth insulator 14 and a sixth insulator 15 are deposited.

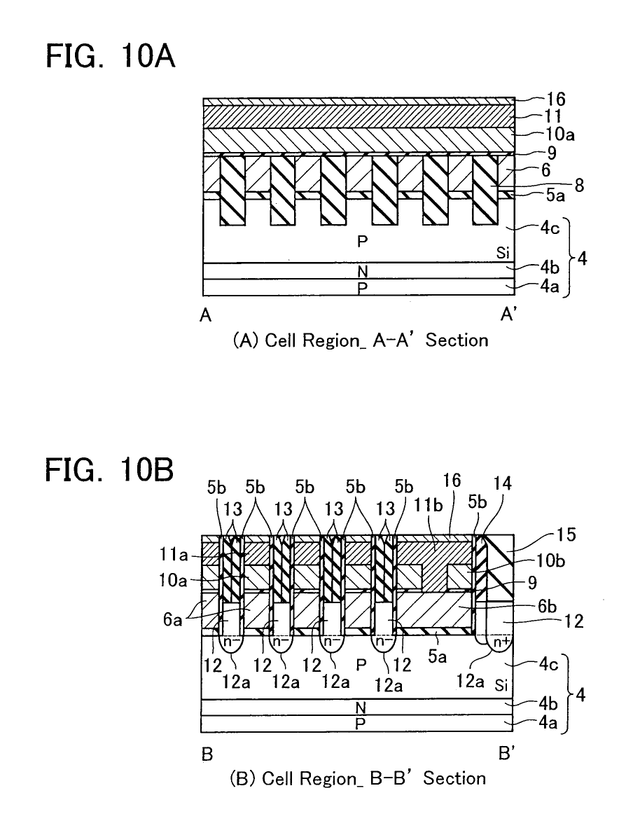

Next, as shown in FIGS. 10A, 10B, the etching technology and CMP are used to remove the fifth insulator 14 and the upper surface portion of the sixth insulator 15 from above the control gate of the cell transistor and the selection gate 1 of the cell transistor, followed by siliciding the upper surface portion of the third insulator 11, which is to be turned into part of the control gate of the cell transistor, to form the silicide film 16.

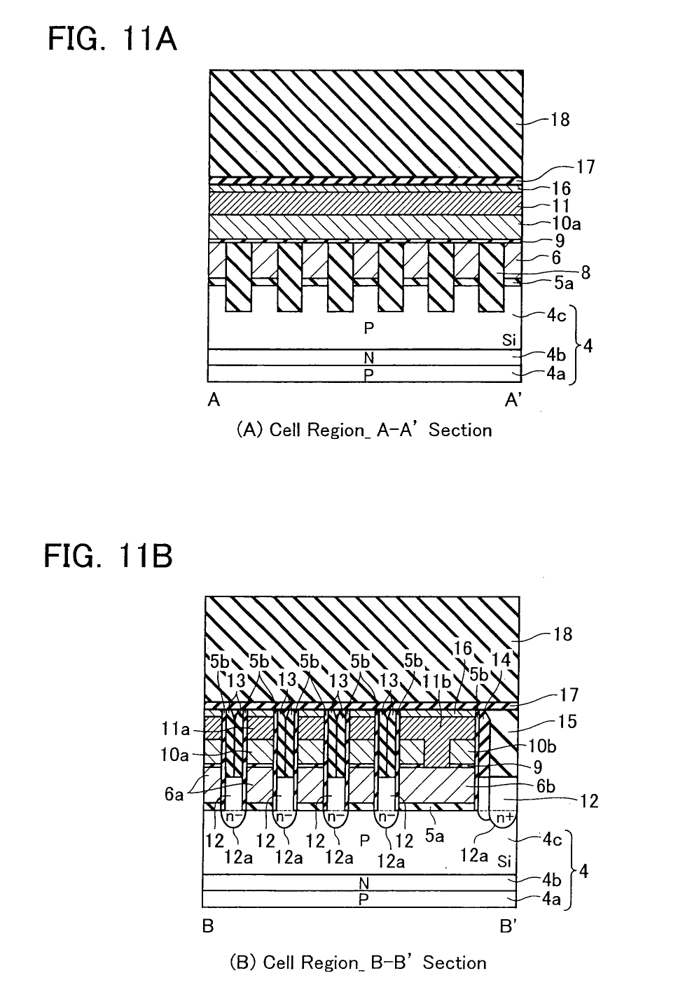

Subsequently, as shown in FIGS. 11A, 11B, a general contact formation step is applied to deposit the interlayer insulators 17, 18. Then, as shown in FIGS. 12A, 12B, a general wire formation step is applied to arrange the contact plugs 19 and a metal wiring material, not shown. Thus, the NAND-type flash EEPROM of the present embodiment can be completed.

As described above, in the present embodiment, the NAND-type semiconductor memory device comprises the first electrode film 6 serving as the floating gates 6a formed at certain intervals on the silicon substrate 4 with the first insulator 5a interposed therebetween, and the control gates 10a, 11a formed on the first electrode film 6 with the second insulator 9 interposed therebetween. The device is configured to inject charge from the control gates 10a, 11a (the second electrode film 10 and the third electrode film 11) into the floating gates 6a (the first electrode film 6). Additionally, in the present embodiment, between the floating gates 6a (the first electrode film 6) on the silicon substrate 4, the selective epitaxial layer 12 is arranged as a conductor with the third insulator 5b interposed therebetween. Therefore, it is possible to provide the NAND-type flash EEPROM with a reduced influence of interference between cells adjacent in the direction of bit lines.

In the selective epitaxial layer 12 of the semiconductor layer formed between portions of the first electrode film 6 (the floating gates 6a), on reading the amount of charge from inside the floating gate 6a, an electric field may be applied. Therefore, the capacity between portions of the first electrode film 6 sandwiching the selective epitaxial layer 12 therebetween can be reduced by the amount of capacity between the lower surface of the first electrode film 6 (the floating gate 6a) and the upper surface of the selective epitaxial layer. As a result, the influence of interference between cells adjacent in the direction of bit lines can be reduced.

In addition, the selective epitaxial layer 12 is epitaxially grown in the trench provided between portions of the first electrode film 6. Accordingly, the depth of the trench can be made shallower. Therefore, it is sufficient to form the fourth insulator 13 only in a shallower region above the selective epitaxial layer 12 with easy deposition of the fourth insulator 13.

The above embodiment also discloses the following configurations (1) and (2).

(1) A method of manufacturing semiconductor memory devices for forming the layer of floating gates 6a composed of the first electrode film 6 and formed at certain intervals in a plane on the silicon substrate 4 with the first insulator 5a interposed therebetween, and the layer of control gates 10a composed of the second electrode film 10 and formed on the layer of floating gates 6a with the second insulator 9 interposed therebetween. The method comprises epitaxially growing the surface of the silicon substrate 4 to form the selective epitaxial layer 12 such that the selective epitaxial layer 12 can be formed between the floating gates 6a on the silicon substrate 4 with the third insulator 5b interposed therebetween.

(2) A method of manufacturing semiconductor memory devices for forming the layer of floating gates 6a composed of the first electrode film 6 and formed at certain intervals in a plane on the silicon substrate 4 with the first insulator 5a interposed therebetween, and the layer of control gates 10a composed of the second electrode film 10 and formed on the layer of floating gates 6a with the second insulator 9 interposed therebetween. The method comprises epitaxially growing the surface of the silicon substrate 4 to form the selective epitaxial layer 12 such that the selective epitaxial layer 12 can be formed between the floating gates 6a on the silicon substrate 4 with the third insulator 5b interposed therebetween such that the selective epitaxial layer 12 has an upper surface located lower than the upper surface of the layer of floating gates 6a.

Although the above embodiment exemplifies the NAND-type flash EEPROM, the present invention is also applicable to other semiconductor memory devices of the NOR-type and so forth, needless to say.

What is claimed is:

1. A method of manufacturing semiconductor memory devices having a floating gate formed on a first insulator provided on a semiconductor substrate and arranged at certain intervals along a plane, and a control gate formed on a second insulator provided on the layer of floating gates, the method comprising:
forming a third insulator on sides in the layer of floating gates; and
forming a semiconductor layer between adjacent portions of the third insulator by selectively epitaxially growing the semiconductor substrate.

2. The method of manufacturing semiconductor memory devices according to claim 1, wherein the semiconductor layer is at least one of an Si layer and an SiGe layer.

3. The method of manufacturing semiconductor memory devices according to claim 1, further comprising implanting impurity ions into the semiconductor substrate to form an impurity layer in a region extending from the semiconductor layer into the semiconductor substrate.

4. The method of manufacturing semiconductor memory devices according to claim 1, said device comprising a layer of control gates further comprising forming a silicide film by siliciding an upper surface of the layer of control gates.

5. A method of manufacturing semiconductor memory devices having a floating gate formed on a first insulator provided on a semiconductor substrate and arranged at certain intervals along a plane, and a control gate formed on a second insulator provided on the layer of floating gates, the method comprising:
forming a third insulator on sides in the layer of floating gates; and
forming a semiconductor layer between adjacent portions of the third insulator by selectively epitaxially growing the semiconductor substrate, the semiconductor layer having an upper surface located lower than the upper surface of the layer of floating gates.

6. The method of manufacturing semiconductor memory devices according to claim 5, wherein the semiconductor layer is at least one of an Si layer and an SiGe layer.

7. The method of manufacturing semiconductor memory devices according to claim 5, wherein the upper surface of the semiconductor layer is located at ⅓ to ¾ of the height from the lower surface of the layer of floating gates.

8. The method of manufacturing semiconductor memory devices according to claim 5, further comprising implanting impurity ions into the semiconductor substrate to form an impurity layer in a region extending from the semiconductor layer into the semiconductor substrate.

9. The method of manufacturing semiconductor memory devices according to claim 5, said device comprising a layer of control gates further comprising forming a silicide film by siliciding an upper surface of the layer of control gates.
